(19) United States
(12) Patent Application Publication
(10) Pub. No.: US 2016/0095219 A1
(43) Pub. Date: Mar. 31, 2016

(54) PRINTED WIRING BOARD AND SEMICONDUCTOR DEVICE HAVING THE SAME

(71) Applicant: IBIDEN CO., LTD., Ogaki-shi (JP)

(72) Inventors: Hajime SAKAMOTO, Ogaki-shi (JP); Ryojiro TOMINAGA, Ogaki-shi (JP)

(73) Assignee: IBIDEN CO., LTD., Ogaki-shi (JP)

(21) Appl. No.: 14/865,273

(22) Filed: Sep. 25, 2015

(30) Foreign Application Priority Data
Sep. 25, 2014 (JP) 2014-195639

(51) Int. Cl. H05K 1/11; H01L 23/498; H05K 1/02; H05K 1/14; H05K 1/18

(52) U.S. Cl. CPC H05K 1/111; H05K 1/144; H05K 1/181; H05K 1/0298; H01L 23/49816

(57) ABSTRACT

A printed wiring board includes a main wiring board having a main wiring pattern, and a sub wiring board mounted to the main board and having a sub wiring pattern such that the sub pattern electrically connects first and second electronic components, first conductor pads positioned to connect the first component to the main board and the sub board and having surfaces such that the first component is mounted onto the surfaces of the first pads via solder bumps, and second conductor pads positioned to connect the second component to the main board and the sub board and having surfaces such that the second component is mounted onto the surfaces of the second pads via solder bumps. The first and second pads are formed such that the surfaces of the first and second pads are formed on the same plane and have the same shape and the same size.

### CROSS-REFERENCE TO RELATED APPLICATIONS

The present application is based upon and claims the benefit of priority to Japanese Patent Application No. 2014-195639, Sep. 25, 2014, the entire contents of which are incorporated herein by reference.

### BACKGROUND OF THE INVENTION

1. Field of the Invention

The present invention relates to a printed wiring board for mounting a first electronic component and a second electronic component that are adjacent to each other, and relates to a semiconductor device having the printed wiring board.

2. Description of Background Art

Japanese Patent Laid-Open Publication No. 2014-49578 describes a printed wiring board in which a main wiring board and a sub wiring board formed in the main wiring board are provided. The entire contents of this publication are incorporated herein by reference.

### SUMMARY OF THE INVENTION

According to one aspect of the present invention, a printed wiring board includes a main wiring board having a main wiring pattern, and a sub wiring board mounted to the main wiring board and having a sub wiring pattern such that the sub wiring pattern electrically connects a first electronic component and a second electronic component, first conductor pads positioned to connect the first electronic component to the main wiring board and the sub wiring board and having surfaces such that the first electronic component is mounted onto the surfaces of the first conductor pads via solder bumps, respectively, and second conductor pads positioned to connect the second electronic component to the main wiring board and the sub wiring board and having surfaces such that the second electronic component is mounted onto the surfaces of the second conductor pads via solder bumps, respectively. The first conductor pads and the second conductor pads are formed such that the surfaces of the first conductor pads and the surfaces of the second conductor pads are formed on the same plane and have the same shape and the same size.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view of a printed wiring board according to a first embodiment of the present invention;

FIG. 2 is a schematic cross-sectional view of a semiconductor device in which first and second electronic components are mounted to the printed wiring board illustrated in FIG. 1;

FIG. 3 is a schematic cross-sectional view illustrating a sub wiring board of the semiconductor device illustrated in FIG. 2 and its vicinity;

FIG. 4 is a schematic plan view of the semiconductor device illustrated in FIG. 2, and illustrates an array relation between first and second conductor pads of the printed wiring board illustrated in FIG. 1;

FIG. 5 is a schematic cross-sectional view of a printed wiring board according to a second embodiment of the present invention;

FIG. 6 is a schematic cross-sectional view illustrating first conductor pads of the printed wiring board illustrated in FIG. 5 and a vicinity thereof;

FIG. 7 is a schematic cross-sectional view of a printed wiring board corresponding to a comparative example of the printed wiring board illustrated in FIG. 6;

FIG. 8 is a schematic cross-sectional view of a printed wiring board according to a third embodiment of the present invention;

FIG. 9 is a schematic cross-sectional view of a semiconductor device in which first and second electronic components are mounted to the printed wiring board illustrated in FIG. 8;

FIG. 10 is an enlarged schematic cross-sectional view of a printed wiring board according to a fourth embodiment of the present invention;

FIG. 11 is a schematic cross-sectional view illustrating a sub wiring board illustrated in FIG. 10 and its vicinity;

FIG. 12 is an enlarged schematic cross-sectional view of a printed wiring board according to a fifth embodiment of the present invention; and

FIG. 13 is a schematic cross-sectional view illustrating a sub wiring board illustrated in FIG. 12 and its vicinity.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

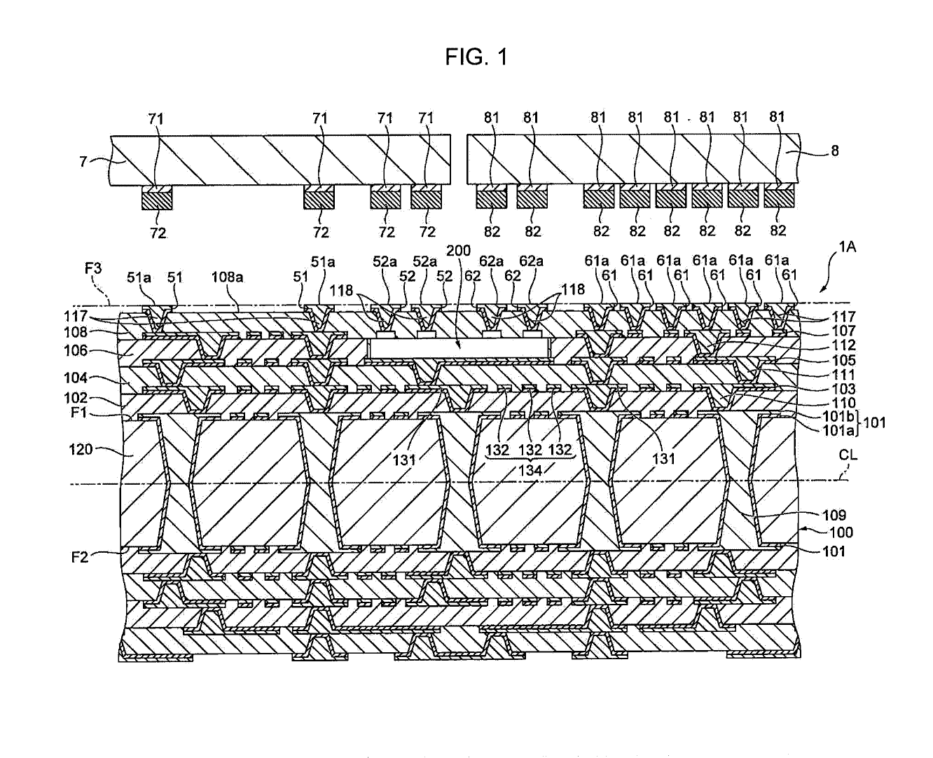

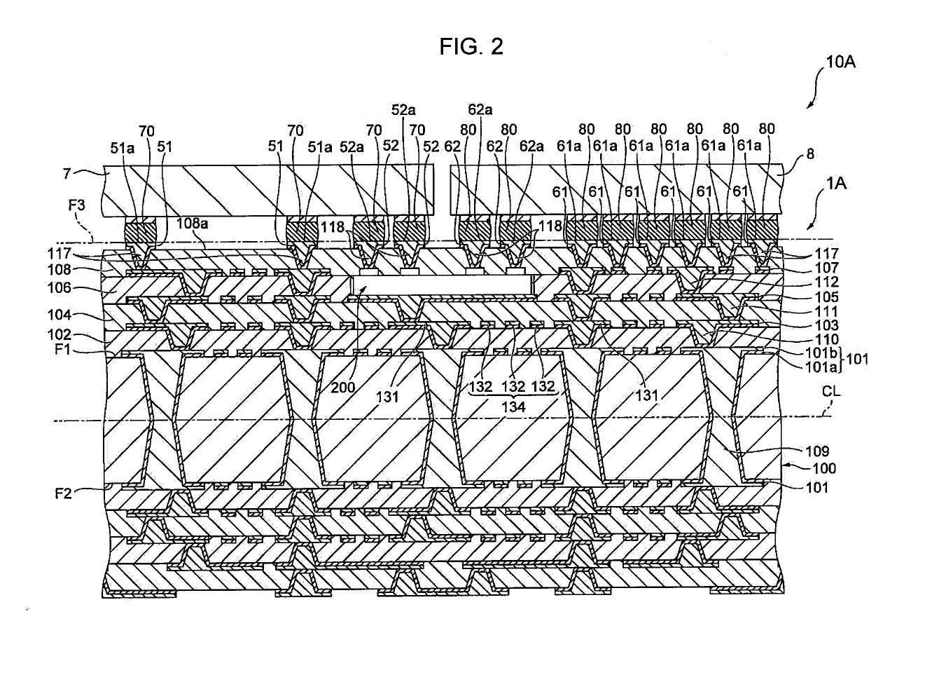

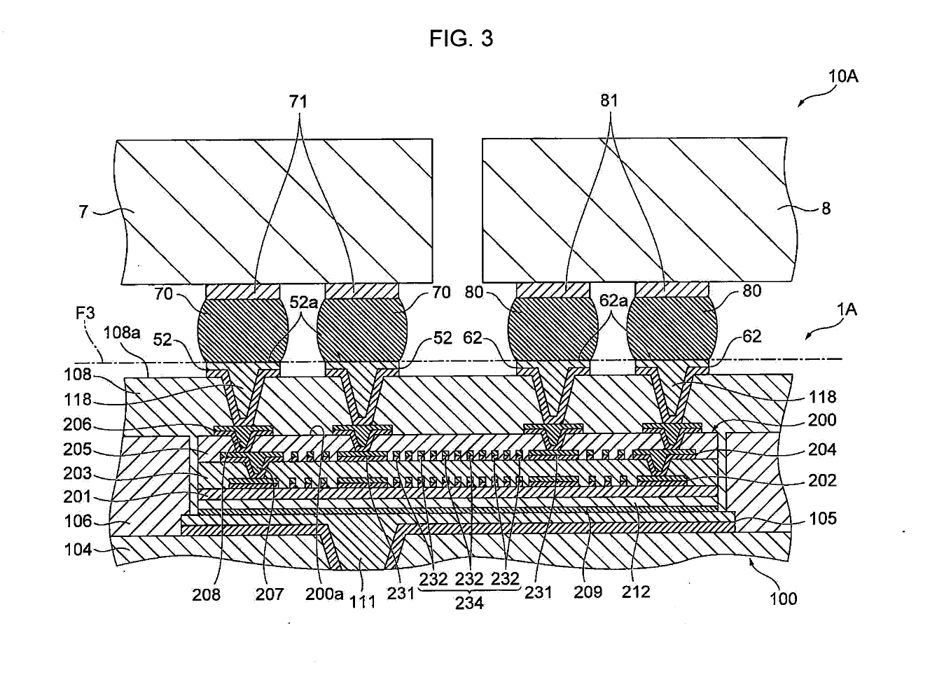

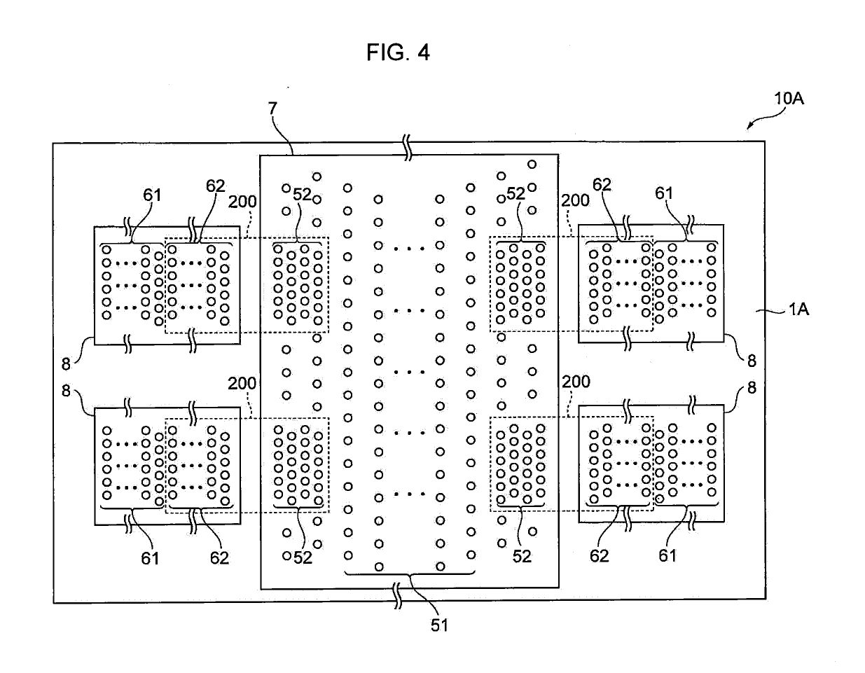

FIG. 1 is a schematic cross-sectional view of a printed wiring board (1A) according to a first embodiment of the present invention. FIG. 2 is a schematic cross-sectional view of a semiconductor device (10A) in which first and second electronic components (7, 8) are mounted to the printed wiring board illustrated in FIG. 1. FIG. 3 is a schematic cross-sectional view illustrating a sub wiring board 200 of the semiconductor device (10A) illustrated in FIG. 2 and its vicinity. FIG. 4 is a schematic plan view of the semiconductor device (10A) illustrated in FIG. 2, and illustrates an array relation between first and second conductor pads (51, 52, 61, 62) of the printed wiring board (1A) illustrated in FIG. 1.

### Printed Wiring Board

As illustrated in FIG. 4, the printed wiring board (1A) according to the present embodiment is a substrate on which a semiconductor element corresponding to a microprocessor (MPU (Micro-Processing Unit)) as the first electronic component 7 and multiple (four) semiconductor elements corresponding to memories (such as DRAM (Dynamic Random Access Memory) and HBM (High Bandwidth Memory)) as the second electronic components 8 are mounted.

As illustrated in FIG. 1, the printed wiring board (1A) includes a main wiring board 100 and a sub wiring board 200. The main wiring board 100 is a multilayer laminated wiring board in which insulating layers and conductor layers are alternately laminated. In the main wiring board 100, the sub wiring board 200 is formed having a sub conductor pattern that is a finer pattern than that of the main wiring board 100. On a surface of the printed wiring board (1A), the first conductor pads (51, 52) that connect to the first electronic component 7 and the second conductor pads (61, 62) that connect, with upper surfaces thereof, to the second electronic components 8 via solders are formed.

### Main Wiring Board

The main wiring board 100 is a build-up multilayer laminated wiring board that is formed by alternately laminating main insulating layers and main conductor layers on each of both main surfaces (F1, F2) of a core substrate 120 in a manner sandwiching the core substrate 120. The main wiring board 100, except a portion where the sub wiring board 200 is embedded, is formed by sequentially laminating layers that have the same functions by the same processes on both sides of a central axis (CL) of the core substrate 120. Therefore, in the following description, only one side (only the main surface (F1) side) is used for the description.

A first main conductor layer 101 that includes a seed layer (101a) and an electrolytic plating layer (101b) is formed on the core substrate 120. The first main conductor layer 101 is covered by a first main insulating layer 102 that is formed on the first main conductor layer 101. The first main insulating layer 102 is formed of, for example, a thermosetting epoxy resin. The seed layer (101a) is a layer made of, for example, titanium, titanium nitride, chromium, nickel, or copper, and can formed by electroless plating, sputtering, or the like. The electrolytic plating layer (101b) is a layer made of copper.

On the first main insulating layer 102, a second main conductor layer 103, a second main insulating layer 104 that covers the second main conductor layer 103, a third main conductor layer 105, a third main insulating layer 106 that covers the third main conductor layer 105, a fourth main conductor layer 107, and a fourth main insulating layer 108 that covers the fourth main conductor layer 107 are further laminated in this order. The second main conductor layer 103, the third main conductor layer 105 and the fourth main conductor layer 107 are each formed from a seed layer and an electrolytic plating layer, similar to the first main conductor layer 101. On the other hand, the second main insulating layer 104, the third main insulating layer 106 and the fourth main insulating layer 108 are each formed of a thermosetting epoxy resin, similar to the first main insulating layer 102. Further, the main insulating layers (102, 104, 106, 108) may also be formed of a thermosetting epoxy resin or a photosensitive resin that contains 30-80% by mass of an inorganic filler.

Further, multiple first main via conductors 110, multiple second main via conductors 111, and multiple third main via conductors 112 are respectively formed in the first main insulating layer 102, the second main insulating layer 104 and the third main insulating layer 106. The main via conductors (110, 111, 112) are each formed in a truncated cone shape and are respectively formed to penetrate through the main insulating layers in which the main via conductors are respectively formed. The first main conductor layer 101 and the second main conductor layer 103 are electrically connected by the first main via conductors 110 that are formed therebetween. The second main conductor layer 103 and the third main conductor layer 105 are electrically connected by the second main via conductors 111 that are formed therebetween. The third main conductor layer 105 and the fourth main conductor layer 107 are electrically connected by the third main via conductors 112 that are formed therebetween.

The third main conductor layer 105 and the first and second main conductor pads (51, 61) (to be described later) are respectively electrically connected by fourth main via conductors 117 that are formed therebetween. Further, a third sub conductor layer 206 of the sub conductor substrate 200 (to be described later) and the first and second sub conductor pads (52, 62) are respectively electrically connected by fifth main via conductors 118 that are formed therebetween. The first main conductor layer 101 that is formed on the main surface (F1) of the core substrate 120 is electrically connected, via through-hole conductors 109 that are provided in the core substrate 120, to the first main conductor layer 101 formed on the main surface on the opposite side.

As illustrated in FIG. 1, some of the main via conductors (110, 111, 112, 117, 118) and the through-hole conductors 109 form stacked conductor vias. Specifically, the main via conductors (110, 111, 112, 117) and the through-hole conductors 109 that are adjacent to the sub wiring board 200 are stacked along a lamination direction of the main wiring board 100 and form the stacked conductor vias. The main conductor layers (101, 103, 105, 107) each include multiple main conductor pads (131, 131 . . . ). Between the main conductor pads (131, 131), a main conductor pattern 134 that includes multiple line-and-space-like main wiring patterns (132, 132, . . . ) is formed. In FIG. 1, the main conductor pads and the main conductor pattern 134 of the second main conductor layer 103 are indicated with reference numeral symbols.

The sub wiring board 200 is embedded in the main wiring board 100. The sub wiring board 200 is positioned on a planar copper layer of the third main conductor layer 105 of the main wiring board 100, and is positioned in parallel to the fourth main conductor layer 107 and the third main via conductors 112. The sub wiring board 200, together with the fourth main conductor layer 107, is covered by the fourth main insulating layer 108 of the main wiring board 100 (the fourth main insulating layer 108 being the outermost layer of the multilayer wiring board), and is sealed inside the sub wiring board 200.

The first main conductor pads (51, 52) and the second main conductor pads (61, 62) for mounting the first electronic component 7 and the second electronic component 8 that are adjacent to each other are formed on an upper surface (108a) of the fourth main insulating layer 108. The first conductor pads (51, 52) include multiple first sub conductor pads 52 that are electrically connected to a sub wiring pattern 234 (see FIG. 3) of the sub conductor substrate 200 and multiple first main conductor pads 51 other than the first sub conductor pads 52. On the other hand, the second conductor pads (61, 62) include multiple second sub conductor pads 62 that are electrically connected to the sub wiring pattern 234 and multiple second main conductor pads 61 other than the second sub conductor pads 62.

As illustrated in FIG. 4, the first main conductor pads 51, the first sub conductor pads 52, the second main conductor pads 61 and the second sub conductor pads 62 are parallel-aligned at predetermined intervals. In the present embodiment, the intervals between the first main conductor pads (51, 51) are wider than the intervals between the first sub conductor pads (52, 52). As described above, the first and second main conductor pads (51, 61) are electrically connected via the fourth main via conductors 117 that are provided in the fourth main insulating layer 108. The first and second sub conductor pads (52, 62) are electrically connected, via the fifth main via conductors 118 that are provided in the fourth main insulating layer 108, to the sub wiring board 200 that is positioned below the fifth main via conductors 118.

In the present embodiment, upper surfaces (51a, 52a) of the first main conductor pads 51 and the first sub conductor pads 52 (corresponding to the first conductor pads) and upper surfaces (61a, 62a) of the second main conductor pads 61 and the second sub conductor pads 62 (corresponding to the second conductor pads) have circular shapes and, as illustrated in FIG. 3, have the same shape (circular shape) and have the same size. In the present embodiment, the upper surfaces (51a, 52a) and the upper surfaces (61a, 62a) have the circular shape. However, as long as all the upper surfaces have the same shape and the same size, the shape of the upper surfaces is not particularly limited and, for example, may be a polygonal shape including a rectangular shape, an elliptical shape, a cross shape, or closed-curve shape. Further, the upper surfaces (51a, 52a) of the first main conductor pads 51 and the first sub conductor pads 52 and the upper surfaces (61a, 62a) of the second main conductor pads 61 and the second sub conductor pads 62 are formed on the same plane (F3). Here, the first and second conductor pads (51, 52, 61, 62) illustrated in the present embodiment and in the following second-fourth embodiments all have the same shape and the same size.

In the present embodiment, as illustrated in FIG. 1, pads 71 are formed on the first electronic component 7; and solder bumps 72 that are connected to the first main conductor pads 51 and the first sub conductor pads 52 for the first electronic component 7 are formed on the pads 71. Similarly, pads 81 are formed on the second electronic component 8; and solder bumps 82 that are connected to the second main conductor pads 61 and the second sub conductor pads 62 for the second electronic component 2 are formed on the pads 82. Further, in the present embodiment, solder bumps are not formed on the upper surfaces (51a, 52a) of the first main conductor pads 51 and the first sub conductor pads 52 and on the upper surfaces (61a, 62a) of the second main conductor pads 61 and the second sub conductor pads 62.

In the present embodiment, as illustrated in FIG. 1, via the solder bumps 72 formed on the pads 71 of the first electronic component 7 and the solder bumps 82 formed on the pads 81 of the second electronic component 8, the first electronic component 7 and the second electronic component 8 are mounted to the printed wiring board (1A), and the semiconductor device (10A) illustrated in FIG. 2 can be obtained.

### Sub Wiring Board

The sub wiring board 200 has a rectangular cross section and is formed in a shape of a cuboid three-dimensionally, and is fixed on the third main conductor layer 105 of the main wiring board 100 via a die attach film (bonding layer) 209 that is positioned at a bottom of the sub wiring board 200. A heat dissipation member 212 and a first sub insulating layer 201 are sequentially positioned on the die attach film 209. In the present embodiment, the heat dissipation member 212 is provided. However, the heat dissipation member 212 may be provided as needed, and can be omitted as illustrated in the fourth and fifth embodiments to be described later.

Here, it is preferable that the heat dissipation member 212 have a thickness in a range of 10-80 μm. In addition to a copper plating layer, the heat dissipation member 212 may also be formed using another metal plating layer, a metal plate or a nano carbon material. By providing the heat dissipation member 212, heat generated during operation of the first and second electronic components (7, 8) can be efficiently released to surroundings via the heat dissipation member 212, and an effect of suppressing influence due to a thermal stress can be achieved. As a result, reliability of the printed wiring board (1A) can be further improved.

Further, on the first sub insulating layer 201, a first sub conductor layer 202, a second sub insulating layer 203, a second sub conductor layer 204, a third sub insulating layer 205 and a third sub conductor layer 206 are laminated in this order. The first sub conductor layer 202 and the second sub conductor layer 204 are electrically connected via first sub conductor vias 207 that are formed in the second sub insulating layer 203. The second sub conductor layer 204 and the third sub conductor layer 206 are electrically connected via second sub conductor vias 208 that are formed in the third sub insulating layer 205. The sub insulating layers (201, 203, 205) are each an insulating layer formed of a photosensitive resin. In this way, by using the photosensitive resin, small-diameter via holes and high-density sub conductor patterns can be easily formed in the sub insulating layers. On the other hand, similar to that in the main wiring board 100, the sub conductor layers (202, 204, 206) are each formed of a seed layer and an electrolytic plating layer.

Here, the first sub conductor layer 202 and the second sub conductor layer 204 are each formed of a seed layer and a copper plating layer. The first sub conductor layer 202 and the second sub conductor layer 204 include multiple sub conductor pads (231, 231 . . . ), and a sub conductor pattern 234 that includes line-and-space-like sub wiring patterns (232, 232, . . . ) is formed between the sub conductor pads (231, 231).

A width of each of the sub wiring patterns 232 that are formed between the sub conductor pads (231, 231) of the sub wiring board 200 illustrated in FIG. 3 and an interval between the sub wiring patterns (232, 232) are respectively narrower than a width and an interval of the main wiring patterns (132, 132) that are formed between the main conductor pads (131, 131) of the main wiring board 100 illustrated in FIG. 1. For example, a pattern width (L) of the sub wiring pattern (232, 232, . . . ) is 3 μm or less and a pattern interval (S) between adjacent sub wiring patterns (232, 232) is 3 μm or less. That is, in the present embodiment, a line and space (L/S) of the sub wiring patterns 232 is (3 μm)/(3 μm) or less. More preferably, the pattern width (L) is 0.5 μm or more, and the pattern interval (S) is 0.5 μm or more. That is, the line and space (L/S) of the sub wiring patterns 232 is (0.5 μm)/(0.5 μm) or more.

### Operation Effects of Printed Wiring Board of First Embodiment

The upper surfaces (51a, 52a) of the first main conductor pads 51 and the first sub conductor pads 52 that are connected to the first electronic component 7 and the upper surfaces (61a, 62a) of the second main conductor pads 61 and the second sub conductor pads 62 that are connected to the second electronic component 8 have the same shape and the same size, and these upper surfaces (51a, 52a, 61a, 62a) are formed on the same plane (F3). Therefore, as illustrated in FIG. 2, connection state (specifically, shapes) of solders (70, 80) that are formed on the conductor pads (51, 52, 61, 62) can be uniformized. As a result, connection states between the conductor pads (51, 52, 61, 62) and the printed wiring board (1A), due to the solders (70, 80), can be stabilized and a highly reliable semiconductor device (10A) can be obtained.

In this way, according to the present embodiment, when the first and second electronic components (7, 8) are mounted to the printed wiring board (1A) via the solders (70, 80), the mountability of the first and second electronic components (7, 8) can be improved. In particular, even when the interval between the first main conductor pads (51, 51) is wider than the interval between the first sub conductor pads (52, 52), these conductor pads (51, 52, 61, 62) are formed to have the same shape and the same size. Therefore, the mountability of the first and second electronic components (7, 8) can be maintained.

Here, in the present embodiment, for example, as needed, it is also possible that the first and second main conductor pads (51, 61) and the first and second sub conductor pads (52, 62) are subjected to a roughening treatment by etching or the like. As a result, surface roughness of the upper surfaces (51a, 61a) of the first and second main conductor pads (51, 61) and the upper surfaces (52a, 62a) of the first and second sub conductor pads (52, 62) is increased. Therefore, adhesion of the upper surfaces with the solders (70, 80) can be enhanced, and a mounting failure of the first and second electronic components (7, 8) can be prevented.

Further, a surface treatment film (oxidation prevention film) may be formed on the first and second main conductor pads (51, 61) and on the first and second sub conductor pads (52, 62). As the surface treatment film, an electroless Ni/Pd/Au film, an electroless Ni/Au film, an OSP (Organic Solderability Preservative) film or the like can be used. By providing the surface treatment film, corrosion of the pad surfaces can be prevented.

### Second Embodiment

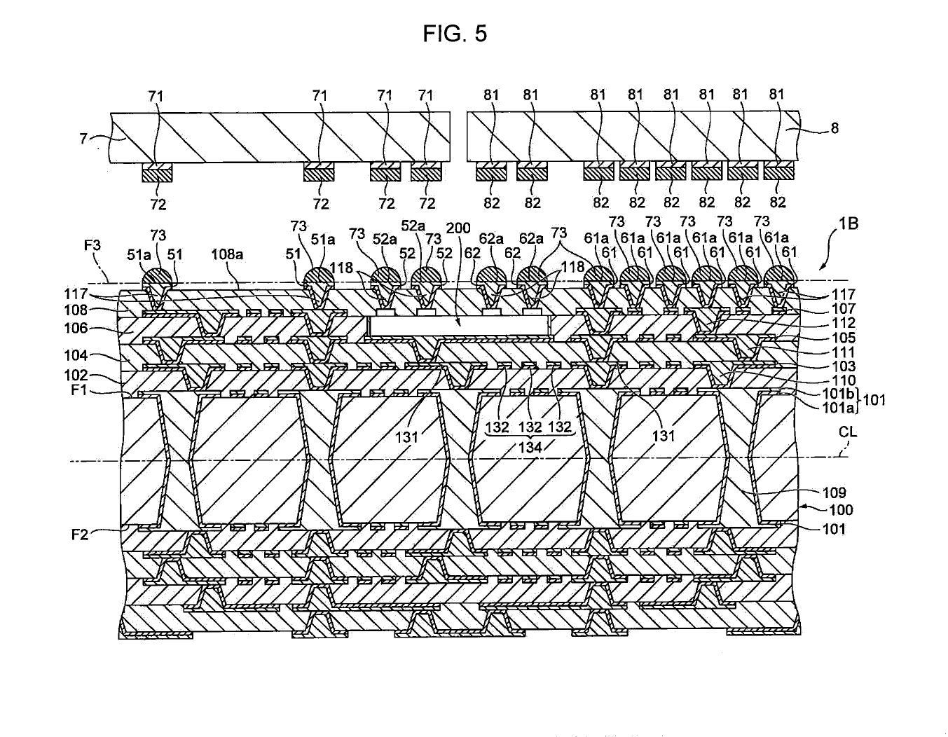

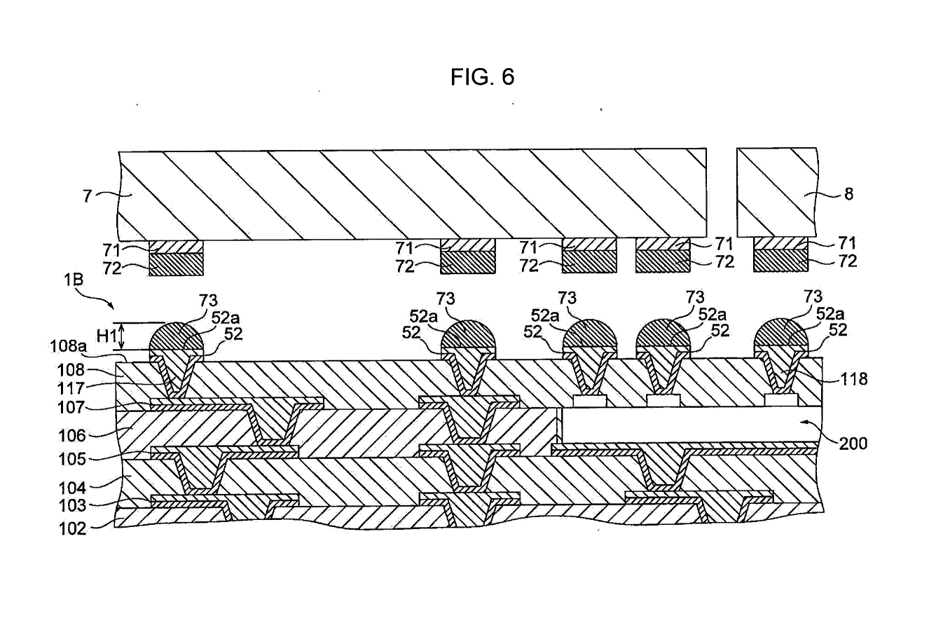

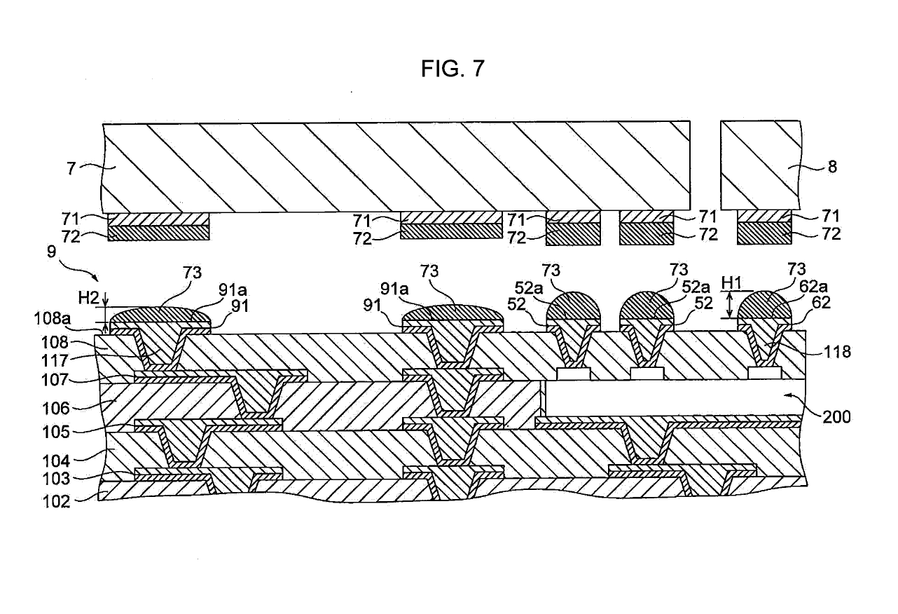

FIG. 5 is a schematic cross-sectional view of a printed wiring board according to a second embodiment of the present invention. FIG. 6 is a schematic cross-sectional view illustrating first conductor pads (51, 52) of the printed wiring board (1B) illustrated in FIG. 5 and a vicinity thereof. FIG. 7 is a schematic cross-sectional view of a printed wiring board 9 corresponding to a comparative example of the printed wiring board (1B) illustrated in FIG. 6. The printed wiring board (1B) of the second embodiment is mainly different from the printed wiring board (1A) of the first embodiment in that solder bumps are provided on the printed wiring board. Therefore, a structure that is common to the first embodiment is indicated using the same reference numeral symbol and detailed description thereof is omitted.

As illustrated in FIGS. 5 and 6, in the present embodiment, similar to the first embodiment, the upper surfaces (51a, 52a) of the first main conductor pads 51 and the first sub conductor pads 52 (corresponding to the first conductor pads) and the upper surfaces (61a, 62a) of the second main conductor pads 61 and the second sub conductor pads 62 (corresponding to the second conductor pads) also have a circular shape and have the same size. The upper surfaces (51a, 52a) of the first main conductor pads 51 and the first sub conductor pads 52 and the upper surfaces (61a, 62a) of the second main conductor pads 61 and the second sub conductor pads 62 are formed on the same plane (F3), and solder bumps 73 are formed on the upper surfaces. Further, an array state of the conductor pads (51, 52, 61, 62) is the same as the array state of the printed wiring board (1A) of the first embodiment illustrated in FIG. 4.

Here, as in a printed wiring board 9 according to a comparative example illustrated in FIG. 7, when the solder bumps 73 are simultaneously formed on conductor pads (52, 62, 91) having upper surfaces (52a, 62a, 91a) of different sizes, variation in heights of the solder bumps 73 occurs. Specifically, the height (H2) of the solder bumps 73 that are formed on the conductor pads 91 that have larger upper surfaces (91a) than the upper surfaces (52a, 62a) of the conductor pads (52, 62) is lower than the height (H1) of the solder bumps 73 that are formed on the conductor pads (52, 62). As a result, the heights (H1, H2) of the solder bumps 73 are different. Therefore, the possibility is increased of a mounting failure of the first and second electronic components such as bump bridging that occurs due to that the solder amount is too large or a solder bonding failure that occurs due to that the solder amount is too small.

However, in the printed wiring board (1B) according to the present embodiment, in addition to the operation effects of the printed wiring board (1A) according to the first embodiment, the following operation effects can be expected. Specifically, in the present embodiment, when the solder bumps 73 are formed on the upper surfaces (51a, 52a) of the first main conductor pads 51 and the first sub conductor pads 52 and on the upper surfaces (61a, 62a) of the second main conductor pads 61 and the second sub conductor pads 62, the height (H1) of the solder bumps 73 that are formed on all the conductor pads (51, 52, 61, 62) can be easily equalized. As a result, a mounting failure of the first and second electronic components (7, 8) such as solder bridging (short circuiting between adjacent solder bumps) that occurs due to that the solder amount is too large or a solder bonding failure (solder is not sufficiently bonded) that occurs due to that the solder amount is too small, can be prevented.

### Third Embodiment

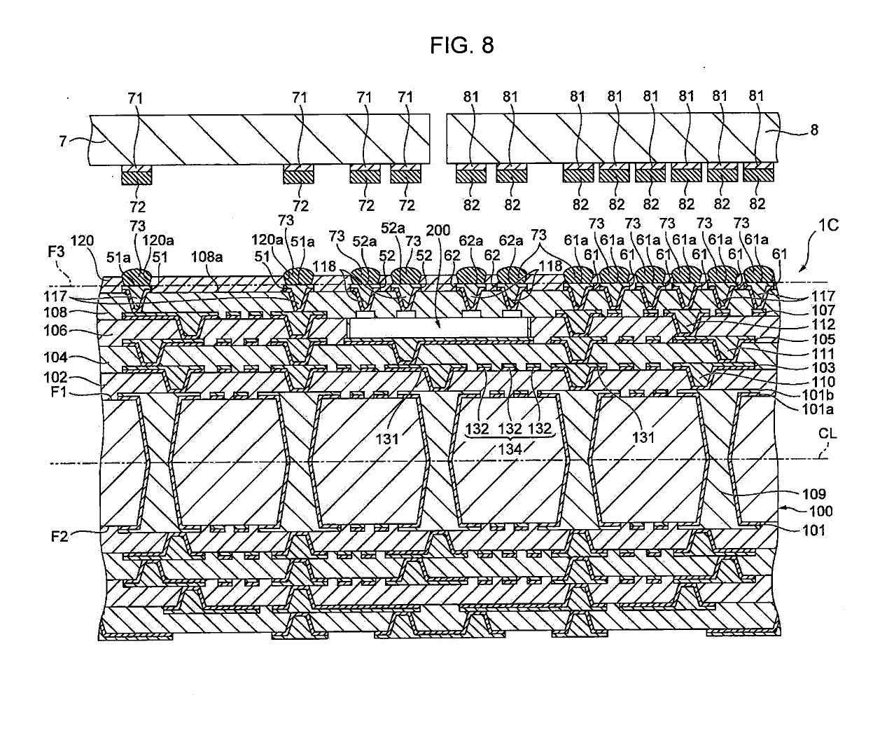

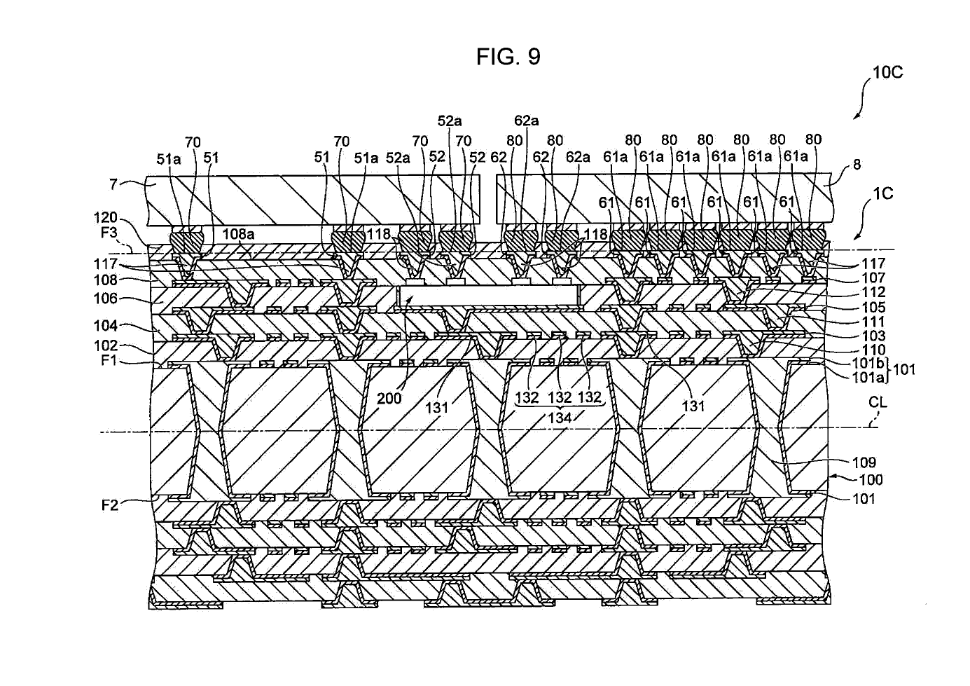

FIG. 8 is a schematic cross-sectional view of a printed wiring board (1C) according to a third embodiment of the present invention. FIG. 9 is a schematic cross-sectional view of a semiconductor device (10C) in which the first and second electronic components (7, 8) are mounted to the printed wiring board (1C) illustrated in FIG. 8. The printed wiring board (1C) of the third embodiment is mainly different from the printed wiring board (1B) of the second embodiment in that a solder resist layer 120 is provided on the printed wiring board (1C). Therefore, a structure that is common to the second embodiment is indicated using the same reference numeral symbol and detailed description thereof is omitted.

As illustrated in FIG. 8, the solder resist layer 120 is formed on the outermost layer of the printed wiring board (1C) according to the present embodiment. In the solder resist layer 120, openings (120a) that have the same opening diameter are formed such that portions of the upper surfaces (51a, 52a) of the first main conductor pads 51 and the first sub conductor pads 52 and portions of the upper surfaces (61a, 62a) of the second main conductor pads 61 and the second sub conductor pads 62 are exposed in the same shape. The solder bumps 73 are respectively filled in the openings (120a). As illustrated in FIG. 9, the first and second electronic components (7, 8) are mounted to the printed wiring board (1C), and the semiconductor device (10C) is manufactured.

In the printed wiring board (1C) according to the present embodiment, in addition to the operation effects of the printed wiring board (1B) according to the second embodiment, the following operation effects can be expected. Specifically, in the present embodiment, similar to the second embodiment, the upper surfaces (51a, 52a) of the first main conductor pads 51 and the first sub conductor pads 52 (corresponding to the first conductor pads) and the upper surfaces (61a, 62a) of the second main conductor pads 61 and the second sub conductor pads 62 (corresponding to the second conductor pads) also have a circular shape and have the same size, and are formed on the same plane (F3). Therefore, the solder resist layer 120 can be stably formed without undulation. Further, in the solder resist layer 120, the sizes of the openings that formed, for example, by exposure and development can be equalized. Further, an array state of the conductor pads (51, 52, 61, 62) is the same as the array state of the printed wiring board (1A) of the first embodiment illustrated in FIG. 4.

### Fourth Embodiment

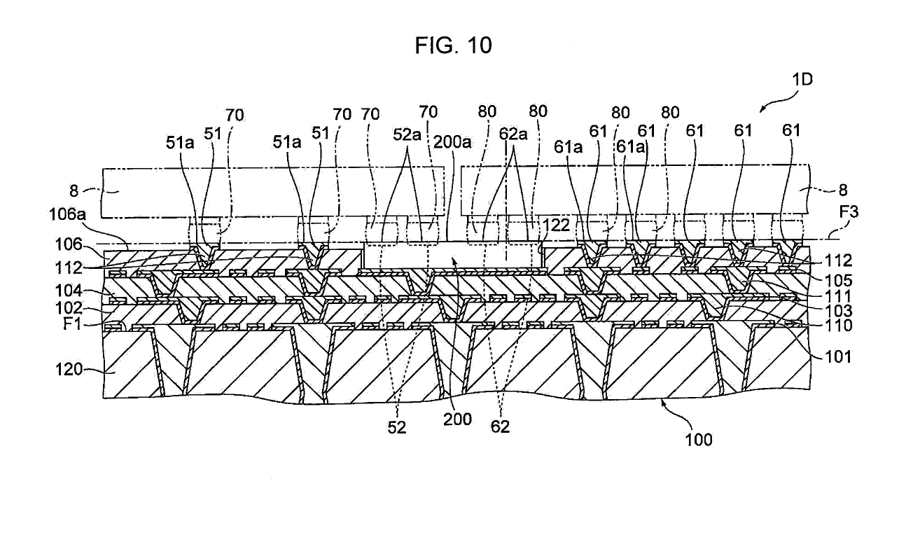

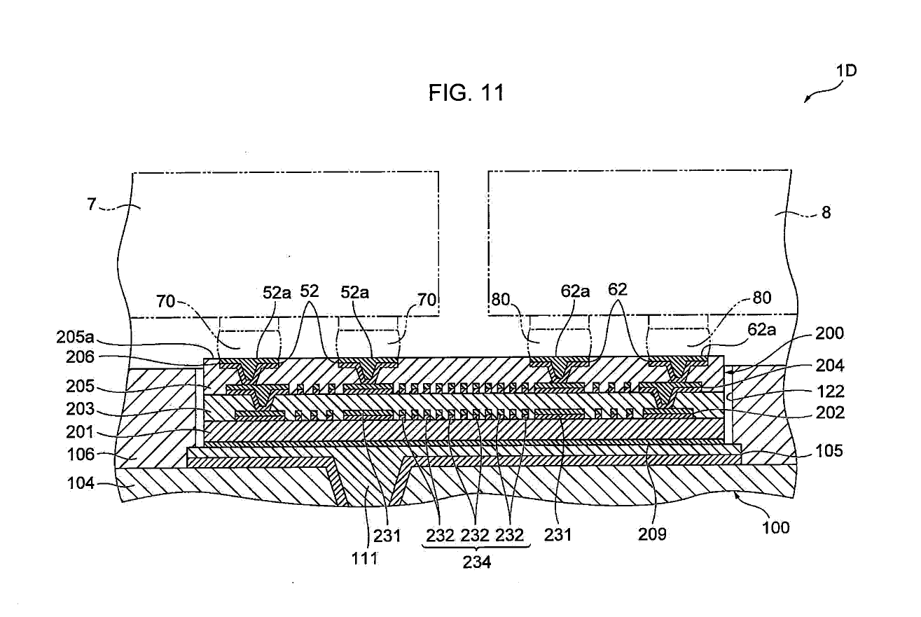

FIG. 10 is an enlarged schematic cross-sectional view of a printed wiring board (1D) according to a fourth embodiment of the present invention. FIG. 11 is a schematic cross-sectional view illustrating a sub wiring board 200 illustrated in FIG. 10 and its vicinity. The printed wiring board (1D) of the fourth embodiment is mainly different from the printed wiring board (1A) of the first embodiment in that the sub wiring board 200, without being embedded in the main wiring board 100, is exposed to the outside; in that the fourth main conductor layer 107 and the fourth main insulating layer 108 of the main wiring board 100 are not provided (in that, instead of the first main conductor layer 107, the first and second main conductor pads (51, 61) and the first and second sub conductor pads (52, 62) are provided); and in that the heat dissipation member 212 is not provided in the sub wiring board 200. Therefore, a structure that is common to the first embodiment is indicated using the same reference numeral symbol and detailed description thereof is omitted.

Specifically, the sub wiring board 200 is positioned in a recess 122 provided in the third main insulating layer 106 of the main wiring board 100, and is fixed to the third main conductor layer 105 via the die attach film 209 (see FIG. 11). That is, the sub wiring board 200 according to the present embodiment, without being covered by a main insulating layer, is exposed to the outside. Therefore, the third sub insulating layer 205 of the sub wiring board 200 forms an outermost layer of the printed wiring board (1D).

In the present embodiment, the first conductor pads (51, 52) that are connected to the first electronic component 7 include the first sub conductor pads 52 that are electrically connected to the sub wiring pattern 232 and the first main conductor pads 51 other than the first sub conductor pads 52. The second conductor pads (61, 62) that are connected to the second electronic component 8 include the second sub conductor pads 62 that are electrically connected to the sub wiring pattern 232 and the second main conductor pads 61 other than the second sub conductor pads 62. That the first main conductor pads 51 and the second main conductor pads 61 are formed in the main wiring board 100 is common to the first embodiment. However, in the present embodiment, the first sub conductor pads 52 and the second sub conductor pads 62 are formed in the sub wiring board 200.

Specifically, as illustrated in FIG. 11, the first sub conductor pads 52 and the second sub conductor pads 62 are formed in the third sub conductor layer 206. The first sub conductor pads 52 and the second sub conductor pads 62 are embedded in the third sub insulating layer 205. As illustrated in FIG. 10, the upper surfaces (51a, 61a) of the first and second main conductor pads (51, 61), and an upper surface (200a) of the sub wiring board 200 that includes the upper surfaces (52a, 62a) of the first and second sub conductor pads (52, 62) and an upper surface (205a) of the third sub insulating layer 205, are formed on the same plane (F3). Similar to the first embodiment, the upper surfaces (51a, 61a) of the first and second main conductor pads (51, 61) and the upper surfaces (52a, 62a) of the first and second sub conductor pads (52, 62) have the same shape (circular shape) and the same size. Further, an array state of the conductor pads (51, 52, 61, 62) is the same as the array state of the printed wiring board (1A) of the first embodiment illustrated in FIG. 4.

In this way, the upper surfaces (51a, 61a) of the first and second main conductor pads (51, 61) and the upper surfaces (52a, 62a) of the first and second sub conductor pads (52, 62) have a circular shape and have the same size and are formed on the same plane (F3). Therefore, similar to the first embodiment, the mountability of the first and second electronic components (7, 8) can be improved.

Further, the upper surfaces (52a, 62a) of the first and second sub conductor pads (52, 62) and the upper surface (205a) of the third sub insulating layer 205 are formed on the same plane, that is, are flush with the upper surface (200a) of the sub wiring board 200. Therefore, when the first and second electronic components (7, 8) are mounted, by using a self-alignment effect, occurrence of solder bridging can be prevented. Therefore, even when array intervals of the first and second sub conductor pads (52, 62) become narrow (for example, 50 μm or less), occurrence of solder bridging can be reliably prevented. As a result, the reliability of the printed wiring board (1D) can be further improved. Further, when the array intervals of the first and second sub conductor pads (52, 62) are wide, similar to the third embodiment, it is also possible that a solder resist layer is provided in which openings are formed on the conductor pads, and solder bumps are filled in the openings.

### Fifth Embodiment

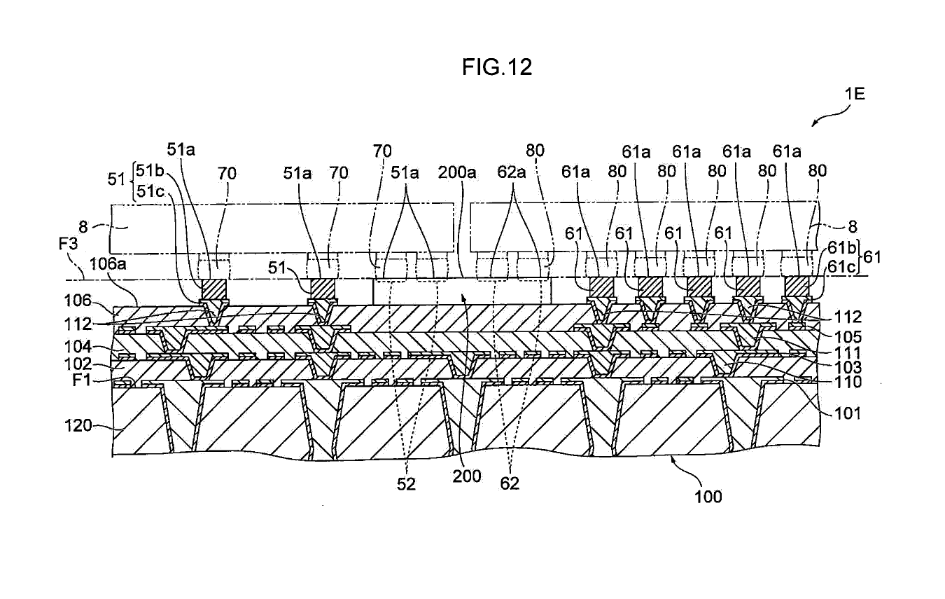

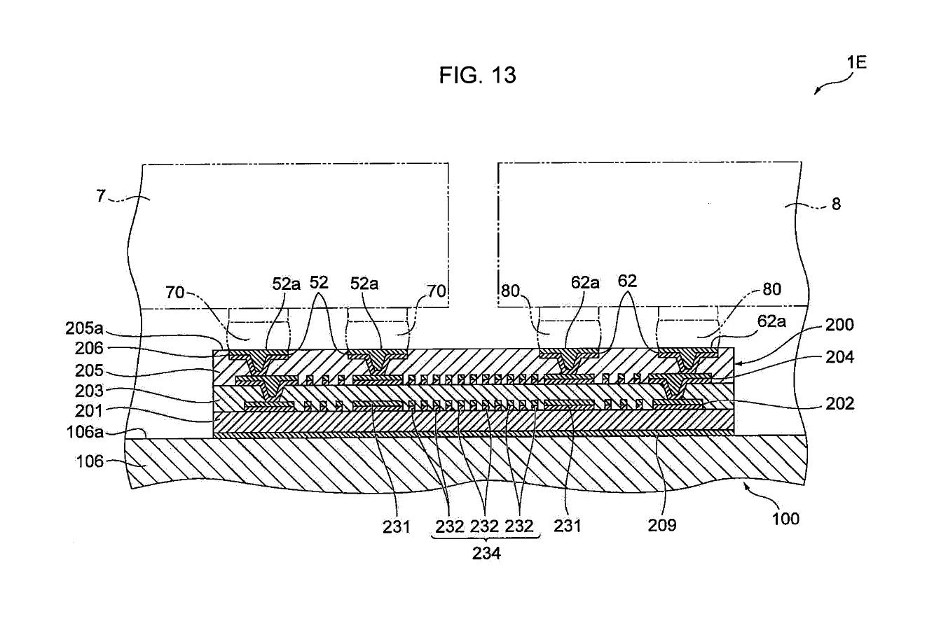

FIG. 12 is an enlarged schematic cross-sectional view of a printed wiring board (1E) according to a fifth embodiment of the present invention. FIG. 13 is a schematic cross-sectional view illustrating a sub wiring board 200 illustrated in FIG. 12 and its vicinity. The printed wiring board (1E) of the fifth embodiment is mainly different from the printed wiring board (1A) of the fourth embodiment in that, without providing the recess 122 for positioning the sub wiring board 200 in the main wiring board 100, the sub wiring board 200 is pasted on a planar surface of the main wiring board 100; and in that conductor members (conductor posts) (51b, 61b) are provided for adjusting positions of the upper surfaces (51a, 61a) of the first and second main conductor pads (51, 61). Therefore, a structure that is common to the fourth embodiment is indicated using the same reference numeral symbol and detailed description thereof is omitted.

Specifically, the sub wiring board 200 is fixed on an upper surface (106a) of the third main insulating layer 106 of the main wiring board 100 via the die attach film 209 (see FIG. 13). Therefore, similar to the fourth embodiment, without being covered by a main insulating layer, the sub wiring board 200 protrudes to the outside from the third main insulating layer 106. The third sub insulating layer 205 and the third sub conductor layer 206 of the sub wiring board 200 form an outermost layer of the printed wiring board (1E).

In the present embodiment, similar to the fourth embodiment, the first conductor pads (51, 52) that are connected to the first electronic component 7 include the first sub conductor pads 52 that are electrically connected to the sub wiring pattern 232 and the first main conductor pads 51 other than the first sub conductor pads 52. The second conductor pads (61, 62) that are connected to the second electronic component 8 include the second sub conductor pads 62 that are electrically connected to the sub wiring pattern 232 and the second main conductor pads 61 other than the second sub conductor pads 62. That the first main conductor pads 51 and the second main conductor pads 61 are formed in the main wiring board 100 is common to the first embodiment. However, in the present embodiment, the first sub conductor pads 52 and the second sub conductor pads 62 are formed in the sub wiring board 200.

Specifically, as illustrated in FIG. 13, the first sub conductor pads 52 and the second sub conductor pads 62 are formed in the third conductor layer 206 of the sub wiring board 200. The first sub conductor pads 52 and the second sub conductor pads 62 are embedded in the third sub insulating layer 205. As illustrated in FIG. 12, the upper surfaces (51a, 61a) of the first and second main conductor pads (51, 61), and an upper surface (200a) of the sub wiring board 200 that includes the upper surfaces (52a, 62a) of the first and second sub conductor pads (52, 62) and an upper surface (205a) of the third sub insulating layer 205, are formed on the same plane (F3). Similar to the first embodiment, the upper surfaces (51a, 61a) of the first and second main conductor pads (51, 61) and the upper surfaces (52a, 62a) of the first and second sub conductor pads (52, 62) have the same shape (circular shape) and the same size. Further, an array state of the conductor pads (51, 52, 61, 62) is the same as the array state of the printed wiring board (1A) of the first embodiment illustrated in FIG. 4.

Further, on the first and second main conductor pads (51, 61), the conductor members (51b, 61b) are formed on base parts (51c, 61c) that are the third sub conductor layer 206. By providing the conductor members (51b, 61b), the upper surfaces (52a, 62a) (upper surface 200a) of the first and second sub conductor pads (52, 62) of the sub conductor substrate 200 and the upper surfaces (51a, 61a) of the first and second main conductor pads (51, 61) are formed on the same plane (F3).

The conductor members (conductor posts) (51b, 61b) are formed as follows. Specifically, after the third conductor layer 206 in the fourth embodiment is formed, a resist is applied to the third conductor layer 206, and openings are formed in the resist layer so as to expose the conductor layer. The conductor members (conductor posts) (51b, 61b) are formed in the openings using a Cu electrolytic plating (electroplating) method and thereafter the resist is removed. As a result, the mountability of the first and second electronic components (7, 8) can be improved. In the present embodiment, the first and second main conductor pads (51, 61) are formed by separately providing the conductor members (conductor posts) (51b, 61b). However, without being limited to this method, for example, it is also possible that the upper surface (52a, 62a) (upper surface (200a)) of the first and second sub conductor pads (52, 62) of the sub conductor substrate 200 and the upper surfaces (51a, 61a) of the first and second main conductor pads (51, 61) are formed on the same plane by reducing the number of layers of the sub wiring board 200 and increasing the thickness of the base parts (51c, 61c) that are the third conductor layer 206 when electroplating is performed.

In this way, the upper surfaces (51a, 61a) of the first and second main conductor pads (51, 61) and the upper surfaces (52a, 62a) of the first and second sub conductor pads (52, 62) have a circular shape and have the same size and are formed on the same plane (F3). Therefore, similar to the operation effects illustrated in the first embodiment, the mountability of the first and second electronic components (7, 8) can be improved.

Further, similar to the operation effects illustrated in the fourth embodiment, the upper surfaces (52a, 62a) of the first and second sub conductor pads (52, 62) and the upper surface (205a) of the third sub insulating layer 205 are formed on the same plane (F3). That is, the upper surface (200a) of the sub wiring board 200 is flush. Therefore, when the first and second electronic components (7, 8) are mounted, by using a self-alignment effect, occurrence of solder bridging can be prevented. Therefore, even when array intervals of the first and second sub conductor pads (52, 62) become narrow (for example, 50 μm or less), occurrence of solder bridging can be reliably prevented. As a result, the reliability of the printed wiring board 1 can be further improved. Further, when the array intervals of the first and second sub conductor pads (52, 62) are wide, similar to the third embodiment, it is also possible that a solder resist layer is provided in which openings are formed on the conductor pads, and solder bumps are filled in the openings.

In the above, embodiments of the present invention are described in detail. However, the present invention is not limited to the above embodiments. Various design modifications can be performed within the scope without departing from the spirit of the present invention as described in appended claims.

In the first-fifth embodiments, with reference to FIG. 4, the first and second conductor pads that are electrically connected to the first electronic component and the second electronic components are described. However, conductor pads that are formed in a printed wiring board are not limited to these conductor pads. As long as the upper surfaces of the first and second conductor pads that are electrically connected to the first electronic component and the second electronic components have the same shape and the same size, upper surfaces of the other conductor pads do not need to have the same shape and the same size.

For example, in the printed wiring boards according to the first-fifth embodiments, mounting pads for mounting a passive electronic component such as a resistor or a capacitor are formed, and shapes and sizes of upper surfaces of these mounting pads may be different from those of the upper surfaces of the first and second conductor pads.

Further, when a so-called POP (Package on Package) structure is adopted in which a printed wiring board illustrated in the first-fifth embodiments is used as a lower substrate, and a substrate positioned above the lower substrate is mounted as an upper substrate, mounting pads for mounting the upper substrate are further formed on an outer periphery of the printed wiring board according to the first-fifth embodiments. In the case, upper surfaces of the mounting pads may have larger sizes than the upper surfaces of the above-described first and second conductor pads.

An electronic component such as an IC chip (semiconductor element) may be mounted on a printed wiring board. The printed wiring board may be a substrate in which insulating layers and conductor layers are alternately laminated. Electronic components such as semiconductor elements that are adjacent to each other may be electrically connected via a sub wiring pattern. Conductor pads may be formed on a surface of the printed wiring board. By connecting the electronic components to the conductor pads via solders, a semiconductor device may be manufactured.

On the surface of the printed wiring board, the conductor pads are connected, with upper surfaces thereof, to the electronic components via solders. However, when the conductor pads have different sizes, and the electronic components are mounted to the printed wiring board via solder bumps, depending on the sizes of the conductor pads, it is possible that variation in connection states of the solders occurs so that a good mountability of the electronic components to the printed wiring board cannot be obtained. In particular, when the conductor pads have different heights, such a phenomenon becomes more noticeable.

A printed wiring board according to an embodiment of the present invention allows improved mountability of multiple electronic components when the electronic components are mounted to the printed wiring board via solders.

A printed wiring board according to an embodiment of the present invention includes a main wiring board in which a main wiring pattern is formed; and a sub wiring board in which a sub wiring pattern is formed, the sub wiring board being provided in the main wiring board. A first electronic component and a second electronic component are electrically connected via the sub wiring pattern. On a surface of the printed wiring board, multiple first conductor pads that are connected, with upper surfaces thereof, to the first electronic component via solders, and multiple second conductor pads that are connected, with upper surfaces thereof, to the second electronic component via solders, are formed. The upper surfaces of the first conductor pads and the upper surfaces of the second conductor pads have the same shape and the same size. The upper surfaces of the first conductor pads and the upper surfaces of the second conductor pads are formed on the same plane.

According to an embodiment of the present invention, the upper surfaces of the first conductor pads that are connected to the first electronic component and the upper surfaces of the second conductor pads that are connected to the second electronic component have the same shape and the same size, and the upper surfaces are formed on the same plane. Therefore, shapes of the solders that are formed on the first conductor pads and the second conductor pads can be uniformized. As a result, connection states between the conductor pads and the printed wiring board, due to the solders, can be stabilized and a highly reliable semiconductor device can be obtained. In this way, according to an embodiment of the present invention, when the first and second electronic components are mounted to the printed wiring board via the solders, the mountability of the first and second electronic components can be improved.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a main wiring board having a main wiring pattern; and
a sub wiring board mounted to the main wiring board and having a sub wiring pattern such that the sub wiring pattern electrically connects a first electronic component and a second electronic component;
a plurality of first conductor pads positioned to connect the first electronic component to the main wiring board and the sub wiring board and having surfaces such that the first electronic component is mounted onto the surfaces of the first conductor pads via solder bumps, respectively; and
a plurality of second conductor pads positioned to connect the second electronic component to the main wiring board and the sub wiring board and having surfaces such that the second electronic component is mounted onto the surfaces of the second conductor pads via solder bumps, respectively,
wherein the plurality of first conductor pads and the plurality of second conductor pads are formed such that the surfaces of the first conductor pads and the surfaces of the second conductor pads are formed on the same plane and have the same shape and the same size.

2. A printed wiring board according claim 1, wherein the surfaces of the first conductor pads and the surfaces of the second conductor pads have one of a circular shape, a rectangular shape and a cross shape.

3. A printed wiring board according claim 1, wherein the surfaces of the first conductor pads and the surfaces of the second conductor pads are roughened surfaces.

4. A printed wiring board according claim 1, wherein the first conductor pads and the second conductor pads have surface treatment films formed on the surfaces of the first conductor pads and the surfaces of the second conductor pads.

5. A printed wiring board according claim 1, further comprising:
a plurality of solder bumps formed on the surfaces of the first conductor pads and the surfaces of the second conductor pads, respectively.

6. A printed wiring board according claim 5, further comprising:
a solder resist layer formed on the main wiring board and the subs wiring board and having a plurality of opening portions exposing portions of the surfaces of the first conductor pads and the surfaces of the second conductor pads, respectively, such that the plurality of solder bumps is filling the plurality of opening portions on the surfaces of the first and second conductor pads, respectively,
wherein the solder resist layer is formed such that the plurality of opening portions has the same opening diameter.

7. A printed wiring board according claim 1, wherein the plurality of first conductor pads comprises a plurality of first main conductor pads and a plurality of first sub conductor pads such that the plurality of first sub conductor pads electrically connects to the sub wiring pattern, the plurality of second conductor pads comprises a plurality of second main conductor pads and a plurality of second sub conductor pads such that the plurality of second sub conductor pads electrically connects to the sub wiring pattern, and the plurality of first conductor pads is formed such that the plurality of first main conductor pads is arrayed at an interval which is greater than an interval of the plurality of first sub conductor pads.

8. A printed wiring board according claim 1, wherein the sub wiring board is embedded inside the main wiring board, and the plurality of first conductor pads and the plurality of second conductor pads are formed on the main wiring board.

9. A printed wiring board according claim 1, wherein the sub wiring board is mounted on the main wiring board such that the sub wiring board is exposed outside the main wiring board, the plurality of first conductor pads comprises a plurality of first main conductor pads and a plurality of first sub conductor pads such that the plurality of first sub conductor pads electrically connects to the sub wiring pattern, the plurality of second conductor pads comprises a plurality of second main conductor pads and a plurality of second sub conductor pads such that the plurality of second sub conductor pads electrically connects to the sub wiring pattern, the plurality of first main conductor pads and the plurality of second main conductor pads are formed on the main wiring board, and the plurality of first sub conductor pads and the plurality of second sub conductor pads are formed on the sub wiring board.

10. A printed wiring board according claim 1, wherein the sub wiring board comprises an insulating layer such that the first and second sub conductor pads are embedded in the insulating layer and have the surfaces on the same plane with respect to a surface of the insulating layer.

11. A printed wiring board according claim 10, wherein the plurality of first conductor pads is formed such that the plurality of first main conductor pads is arrayed at an interval which is greater than an interval of the plurality of first sub conductor pads.

12. A printed wiring board according claim 1, wherein the plurality of first conductor pads and the plurality of second conductor pads are formed such that the plurality of first conductor pads and the plurality of second conductor pads have the same shape and the same size.

13. A printed wiring board according claim 1, wherein the plurality of first conductor pads comprises a plurality of first main conductor pads and a plurality of first sub conductor pads such that the plurality of first sub conductor pads electrically connects to the sub wiring pattern, the plurality of second conductor pads comprises a plurality of second main conductor pads and a plurality of second sub conductor pads such that the plurality of second sub conductor pads electrically connects to the sub wiring pattern, the plurality of first main conductor pads and the plurality of second main conductor pads are formed on the main wiring board, the plurality of first sub conductor pads and the plurality of second sub conductor pads are formed on the sub wiring board, and the main wiring pattern is formed between the first and second main conductor pads and the sub wiring pattern is formed between the first and second sub conductor pads such that the sub wiring pattern has a pattern width and a pattern interval which are narrower than a pattern width and a pattern interval of the main wiring pattern.

14. A printed wiring board according claim 1, wherein the first electronic component is a semiconductor microprocessor component, and the second electronic component is a semiconductor memory component.

15. A printed wiring board according claim 1, wherein the plurality of first conductor pads comprises a plurality of first main conductor pads and a plurality of first sub conductor pads such that the plurality of first sub conductor pads electrically connects to the sub wiring pattern, and the plurality of second conductor pads comprises a plurality of second main conductor pads and a plurality of second sub conductor pads such that the plurality of second sub conductor pads electrically connects to the sub wiring pattern.

16. A printed wiring board according claim 1, wherein the plurality of first conductor pads comprises a plurality of first main conductor pads and a plurality of first sub conductor pads such that the plurality of first sub conductor pads electrically connects to the sub wiring pattern, the plurality of second conductor pads comprises a plurality of second main conductor pads and a plurality of second sub conductor pads such that the plurality of second sub conductor pads electrically connects to the sub wiring pattern, the plurality of first main conductor pads and the plurality of second main conductor pads are formed on the main wiring board, and the plurality of first sub conductor pads and the plurality of second sub conductor pads are formed on the sub wiring board.

17. A printed wiring board according claim 8, wherein the plurality of first conductor pads comprises a plurality of first main conductor pads and a plurality of first sub conductor pads such that the plurality of first sub conductor pads electrically connects to the sub wiring pattern, the plurality of second conductor pads comprises a plurality of second main conductor pads and a plurality of second sub conductor pads such that the plurality of second sub conductor pads electrically connects to the sub wiring pattern, the plurality of first main conductor pads and the plurality of second main conductor pads are formed on the main wiring board, and the plurality of first sub conductor pads and the plurality of second sub conductor pads are formed on the sub wiring board.

18. A semiconductor device, comprising:
the printed wiring board of claim 1;
the first electronic component mounted to the printed wiring board through the first and second conductor pads; and
the second electronic component mounted to the printed wiring board through the first and second conductor pads.

19. A semiconductor device, comprising:
the printed wiring board of claim 8;
the first electronic component mounted to the printed wiring board through the first and second conductor pads; and
the second electronic component mounted to the printed wiring board through the first and second conductor pads.

20. A semiconductor device, comprising:
the printed wiring board of claim 9;
the first electronic component mounted to the printed wiring board through the first and second conductor pads; and
the second electronic component mounted to the printed wiring board through the first and second conductor pads.
